(19) United States
(12) Patent Application Publication
(10) Pub. No.: US 2008/0246134 A1
(43) Pub. Date: Oct. 9, 2008

(54) Package-Borne Selective Enablement Stacking

(75) Inventors: Leland Szewerenko, Austin, TX (US); James Douglas Wehrly, Austin, TX (US)

Correspondence Address: FISH & RICHARDSON P.C., P.O BOX 1022, Minneapolis, MN, 55440-1022, US

(73) Assignee: STAKTEK GROUP L.P., Austin, TX (US)

(21) Appl. No.: 11/696,170

(22) Filed: Apr. 3, 2007

(51) Int. Cl. H01L 23/58

(52) U.S. Cl. 257/686; 257/E23.002

(57) ABSTRACT

The present invention provides a system and method for selectively stacking and interconnecting leaded packaged integrated circuit devices. In preferred embodiments, the plastic body of one or more leaded packaged ICs bear conductive traces that create circuitry to provide stacking related electrical interconnections between the constituent ICs of a stacked module without the use of separate interposers or carrier structures. Typically, the circuitry is borne by the body of the upper one of the ICs of a two-IC leaded package stack to implement stacking-related connections between the constituent ICs.

### TECHNICAL FIELD

The present invention relates to aggregating integrated circuits and, in particular, to stacking integrated circuits.

### BACKGROUND

A variety of techniques are used to stack packaged integrated circuits into a module. Some require that the circuits be encapsulated in special packages, while others use circuits in conventional packages. Both leaded and BGA (e.g., CSP) type packaged integrated circuits (ICs) have been stacked. Although array packaging has become widely adopted, leaded packages are still employed in large volumes in low cost applications such as, for example, flash memory, which typically is packaged in thin small outline packages otherwise known as TSOPs.

When leaded packages such as TSOPs are stacked, a variety of techniques have been employed. In some cases, the leads alone of packaged circuits have been used to create the stack and interconnect its constituent elements. In other techniques, structural elements such as printed circuit boards (PCBs) are used to create the stack and interconnect the constituent elements.

Circuit boards and rail-like structures in vertical orientations have been used for years to provide interconnection between stack elements. For example, in U.S. Pat. No. 5,514,907 to Moshayedi, a technique is described for creating a multi-chip module from surface-mount packaged memory chips. The devices are interconnected on their lead-emergent edges through printed circuit boards oriented vertically to a carrier or motherboard that is contacted by connective sites along the bottom of the edge-placed PCBs. The PCBs have internal connective rail-like structures or vias that interconnect selected leads of the upper and lower packaged memory chips. Japanese Patent Laid-open Publication No. Hei 6-77644 discloses vertical PCBs used as side boards to interconnect packaged circuit members of the stack. In U.S. Pat. No. 5,266,834 to Nishi et al., one depicted embodiment illustrates a stack created by selective orientation of the leads of particularly configured stack elements, while in U.S. Pat. No. 5,343,075 to Nishino, a stack of semiconductor devices is created with contact plates having connective lines on inner surfaces to connect the elements of the stack. Another technique for stacking leaded packaged ICs with carrier structures or interposers oriented along lead bearing sides of packaged devices such as TSOPs is disclosed by the present assignee, Staktek Group L.P., in U.S. Pat. No. 6,608,763 issued Aug. 19, 2003, to Burns et al., which is incorporated herein by reference for all purposes.

Many of the previously cited and known techniques for using PCBs and similar interposer structures for stacking leaded packaged devices into modules have evolved to meet the increased connective complexity presented by, for example, stacking memory components that have two or more chip enables per packaged device. Connectivity complexities, however, can arise in any applications where there is a need to connect non-adjacent leads of the module ICs. In some cases, this evolution has included use of interposer designs that employ four metal-layer designs to implement the more complex connection strategies required by more complex devices. Size limitations and other factors applicable to packaged IC stacking, however, have led to complexities in via and connection strategies. For example, trace routing and other connective requirements for interposers or carrier structures used in many applications may require the use of buried vias and/or blind vias. In various applications, the micro vias are used for blind vias. The use of multi-layer PCBs with buried vias and blind vias to address complex routing and other connective demands, however, increases costs and may present quality issues due to tight tolerances required.

What is needed, therefore, is a new system and method for stacking leaded packaged devices that accommodates interconnection between the constituent ICs of a multi-package stacked module without use of an interposer or carrier structure but yet can implement more complex connection strategies.

### SUMMARY

The present invention provides a system and method for selectively stacking and interconnecting leaded packaged integrated circuit devices. In preferred embodiments, the body of one or more leaded packaged ICs bears circuitry to provide stacking-related electrical interconnections between the constituent ICs of a stacked module without the use of separate interposers or carrier structures. Typically, the circuitry is borne by the body of the upper one of the ICs of a two-IC leaded package stack to implement stacking-related connections between the constituent ICs. In a preferred two-IC stack embodiment, at least some connections between respective upper and lower ICs are implemented by interconnection of respective leads of the upper and lower stack ICs while stacking-related connections are implemented with the circuitry borne by the body of the upper one of the ICs.

### BRIEF DESCRIPTION OF THE DRAWINGS

FIG. 1 depicts an exemplar circuit module in accordance with an embodiment illustrating exemplar circuitry borne by the body of the upper leaded packaged IC.

FIG. 2 depicts a plan view of the stack depicted in FIG. 1 further illustrating, the circuitry borne by the body of the upper IC.

FIG. 3A depicts a side view of a portion of an exemplar stack in accordance with an embodiment.

FIG. 3B depicts a side view of a portion of an exemplar stack in accordance with an alternative embodiment.

FIG. 4 is an enlarged perspective view of an exemplar stack illustrating circuitry borne by the body of the upper IC to implement selective stacking related connections.

### DETAILED DESCRIPTION

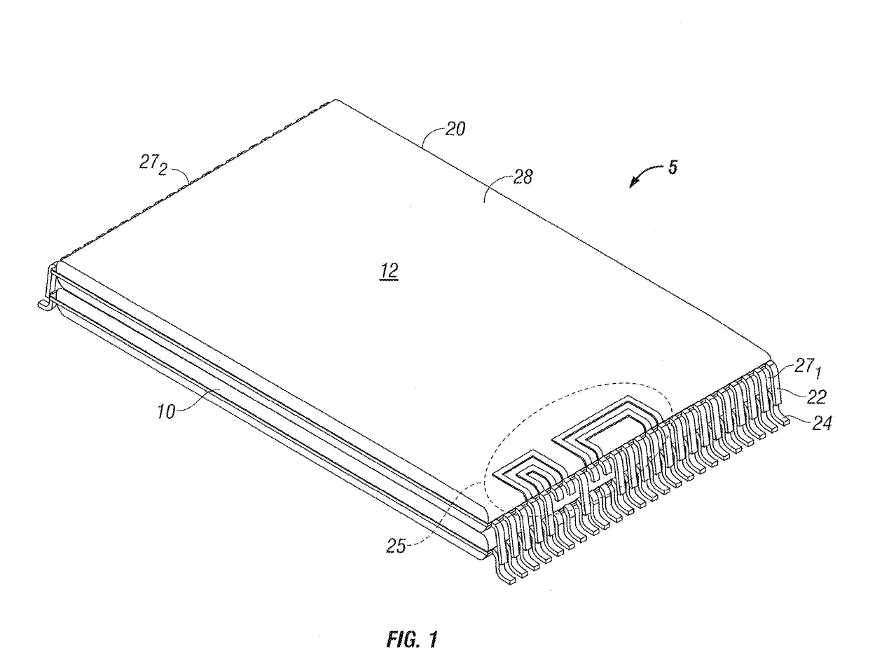

FIG. 1 depicts an exemplar circuit module 5 in accordance with an embodiment illustrating exemplar circuitry borne by the body of the upper leaded packaged IC. As shown, module 5 employs circuitry 25 shown within the dotted line circle that implements electrical connections devised to allow selective enablement of upper and lower ICs 20 and 10, respectively.

Each of ICs 10 and 20 are, in the described preferred embodiment, encapsulated memory circuits disposed in thin small outline packages known as TSOPs. Each of the constituent ICs of the depicted exemplar module 5 exhibit IC bodies 12, while upper IC 20 exhibits leads 22 and lower IC 10 exhibits leads 24. In the depicted embodiment of stacked module 5, as shown in further detail in later FIGS., leads 22 of upper IC 20 differ from leads 24 of lower IC 10 in that leads 22 of upper IC 20 extend down from the upper IC 20 to lower IC 10 at certain respective lead positions along edges or sides 27₁ and 27₂ of module 5. Those of skill will recognize that techniques other than direct lead-to-lead connection may be employed to effectuate the connections illustrated as direct lead-to-lead connection shown in the embodiment shown in FIG. 1. For example, but less frequently, a carrier structure or interposer such as those depicted in U.S. patent application Ser. No. 11/452,531, filed Jun. 14, 2006 or U.S. patent application Ser. No. 11/452,532, filed Jun. 14, 2006 (both of which being assigned to Staktek Group L.P.) may be employed to provide the direct lead-to-lead connections between respective ICs of module 5 but typically, there are efficiencies in direct lead-to-lead connection between selective corresponding leads as illustrated which, when used with circuitry 25, provide connective circuitry to implement a stacked module. As those of skill will recognize, leads are sometimes referred to as pins.

Other package types may be used with the present invention as well as packaged circuits other than memories but, as described here with examples, many embodiments will be implemented with memories in TSOP packaging. Flash memory circuits implemented in TSOP packaging are one type of preferred constituent ICs 10 and 20. In the illustrated embodiment, there is no gap between IC 10 and IC 20, but embodiments may exhibit an air gap between constituent ICs or, alternatively, a heat transference material or adhesive between the ICs. The employed adhesive may be thermally conductive.

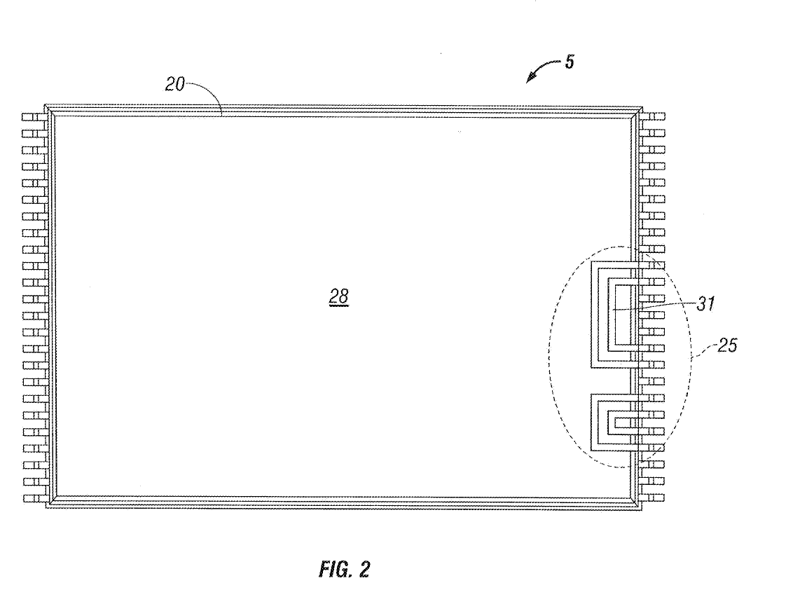

FIG. 2 depicts a plan view of the stack depicted in FIG. 1 further illustrating circuitry 25 borne by body 12 of upper IC 20. Body 12 is typically but not always, plastic. Circuitry 25 is typically comprised of plural traces 31 that provide stacking-related connections between upper IC 20 and lower IC 10. Stacking-related connections can include, for example, selective enablement so that only one of the constituent ICs of a circuit module 5 is enabled at a time.

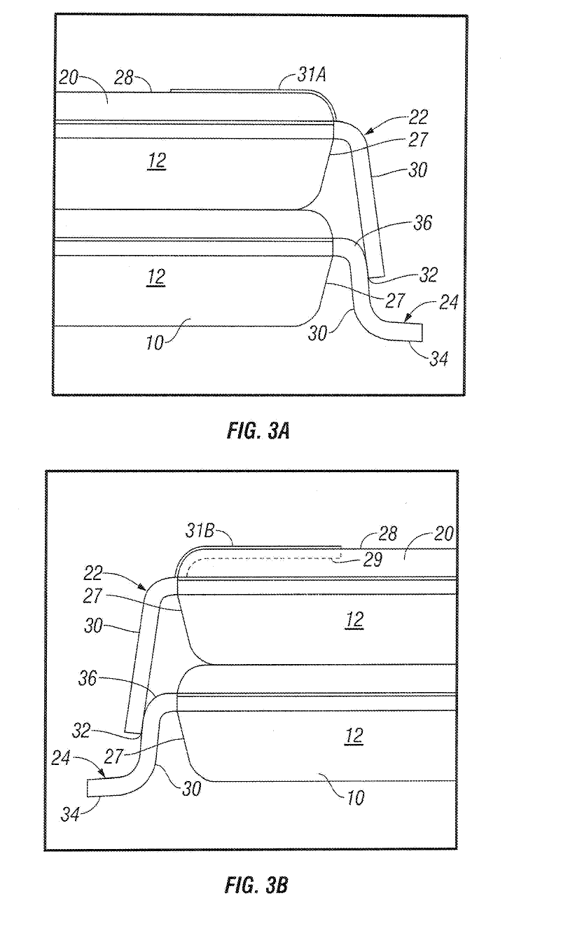

Circuitry 25 may be implemented in a variety of ways including, as a non-limiting example, printing conductive traces 31 with a conductive ink that is preferably curable. Other exemplar alternative constructions for traces 31 may include dispensable conductive materials, for example, such as conductive particles suspended in an adhesive, a conductive ink, or conductive epoxy. Solder paste is one type of such conductive material that could be used for traces 31. Conductive traces 31 may also be devised with a conductive pattern that is constructed on a release liner, laminated or transferred to the body of the IC and then the release liner pulled away. In any case, traces are typically to be borne by the surface of body 12 of IC 20. Exemplar conductive traces that are borne by the surface 28 of an IC are identified in the Figs as 31A while traces that reside in channels or grooves imposed in body 12 will be identified as traces 31B. Later FIG. 3A illustrates traces 31A that reside on the surface 28 of body 12. As another example, circuitry 25 may also be implemented with conductive traces that are plated conductive material residing either on the surface 28 of body 12, or in etched channels or grooves 29 imposed with, for example, a laser. FIG. 3B illustrates an example of circuitry 25 implemented with traces 31B implemented as plated conductive material residing in channels 29 disposed in body 12 of IC 20.

FIGS. 3A and 3B depict in more detail leads 24 and 22. Plural leads emerge from peripheral walls, sides or edges 27 of ICs 20 and 10. Leads may emerge from one or more sides of the leaded packaged ICs. Leads 22 of IC 20 emergent from peripheral side 27₁ of upper IC 20 have a long transit section 30 that brings lead 22 into proximity with lead 24 to allow electrical contact between the respective leads that may be realized with solder or other connective 32. As another example, the leads may be welded together. Illustrated lead 24 of lower IC 10 is shown as having foot 34, shoulder 36 and transit section 30. In practice, leads 22 and 24 and, in particular, transit sections 30, are surfaces from which heat from the internal chip(s) of the respective TSOPs may be dissipated. Shoulder 36 of lead 24 can extend from and include the planar part of lead 24 emergent from peripheral wall 27 to the end of the curvature into transit section 30. Transit section 30 is often a substantially straight path but may exhibit curvature. As leads 24 emerge from the package periphery 27, a supportive shelf or plane is created or defined by the heads of the plurality of leads on a side. These features of leads 24 are present in conventional TSOP packaged memory circuits such as flash memory available from major suppliers of packaged memories. Foot 34 is provided to allow the mounting of the IC on a mounting field provided typically by a printed circuit or other signal transit board. Surface mount soldering techniques or other methods known in the art may be employed to make such connections. Those of skill will recognize that various combinations of lead features may be present in different packaged ICs that may be deployed in embodiments of the present invention.

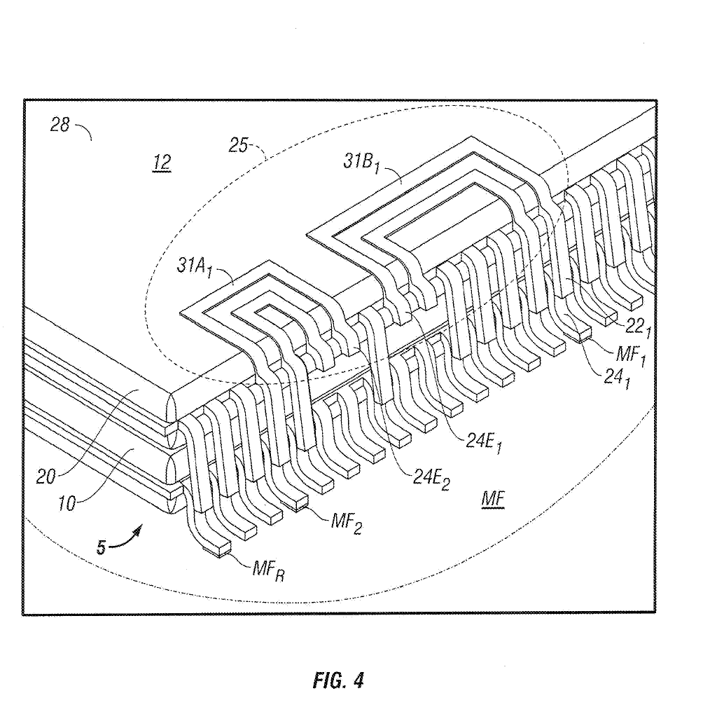

FIG. 4 is an exemplar enlarged depiction of a portion of a circuit module 5 in accordance with an embodiment. Circuitry 25 (within the dotted line circle) consists of exemplar traces 31A and 31B that participate in connections that participate in realization of selective connection between a mounting field exemplified by contacts MF1-MFn shown below feet 34 of leads 24 of lower IC 10 and selected enable or other functional pins of upper IC 20. The illustration of FIG. 4 depicts two of many available alternatives for disposing traces to be borne by body 12 of an IC. Trace 31A exemplifies traces that reside on the surface 28 of body 12 of IC 20 (e.g., as conductive ink) and trace 31B exemplifies traces that reside in channels 29 disposed onto surface 28 of body 12 of IC 20. Both types of traces are shown in FIG. 4 merely to illustrate a few of the modes available to implement traces borne by body 12 of the IC but, in practice, typical traces in a circuit module 5 will all be implemented alike.

Following is a description of an exemplar connection in which trace 31B₁ participates. MF₁ is a contact pad in a mounting field MF to which module 5 is connected. MF may be, for example, on a motherboard. MF₁ is connected to lead 24₁ (through the foot of that lead 24₁). Lead 24₁ is connected to lead 22₁ which is connected to trace 31B₁ that is borne by body 12 of IC 20 and extends about to lead 24E₁. Thus, if site MF₁ is the source for an enable signal and leads 22₁ and 24₁ are in a N/C position on ICs 20 and 10, respectively, and lead 24E₁ is an enable pin for IC 20, persons of skill will understand that IC 20 can be enabled by a signal applied to MF₁. Those of skill will notice that lead 24E₁ has been truncated or clipped to avoid connection with the corresponding lead 24 of IC 10 because the enable signal conveyed through trace 31B₁ is devised to enable IC 20 while leaving IC 10 unaffected. No carrier structure or interposer was required to selectively enable IC 20. Another exemplar connection identified between MF₂ and 24E₂ is realized through trace 31A₁ as shown. Provision of multiple such connective paths such as the example of one such path as illustrated between MF₁ and 24E₁ illustrate the flexibility of the embodiments through which realization of a variety of intra-stack and/or stacking related connections in circuit module 5 can be implemented.

Although the present invention has been described in detail, it will be apparent that those skilled in the art that the invention may be embodied in a variety of specific forms and that various changes, substitutions and alterations can be made without departing from the spirit and scope of the invention. The described embodiments are only illustrative and not restrictive and the scope of the invention is, therefore, indicated by the following claims.

1. A circuit module comprised of:
a first packaged integrated circuit and a second packaged integrated circuit, the first and second packaged integrated circuits stacked vertically one above the other, each of the first and second packaged integrated circuits having a body and leads emergent from at least one peripheral side of said body; and
circuitry borne on the body of the second packaged integrated circuit, the circuitry being comprised of at least one trace in a conductive path between a no-connect pin and an enable pin of the second packaged integrated circuit.

2. The circuit module of claim 1 in which the body of the first and second packaged integrated circuits is comprised of plastic.

3. The circuit module of claim 1 in which the at least one trace of the circuitry borne on the body of the second packaged integrated circuit is comprised of conductive ink.

4. The circuit module of claim 1 in which the at least one trace of the circuitry borne on the body of the second packaged integrated circuit is comprised of plated conductive material.

5. The circuit module of claim 1 in which the at least one trace of the circuitry borne on the body of the second packaged integrated circuit resides at least in part in a channel disposed in the body of the second packaged integrated circuit.

6. The circuit module of claim 5 in which the channel disposed in the body of the second packaged integrated circuit is etched.

7. A circuit module comprised of:
a first leaded packaged integrated circuit; and
a second leaded packaged integrated circuit stacked above the first leaded packaged integrated circuit, each of the first and second packaged integrated circuits being comprised of a body having emergent leads with the body of the second packaged integrated circuit bearing a first conductive trace that connects a first pin and a second pin of the second packaged integrated circuit.

8. The circuit module of claim 7 in which the first pin is a no-connect pin.

9. The circuit module of claim 7 in which the second pin is an enable pin.

10. The circuit module of claim 7 in which the first pin is a no-contact pin and the second pin is an enable pin.

11. The circuit module of claim 7 in which the first trace is comprised of plated conductive material.

12. The circuit module of claim 7 in which the first and second packaged integrated circuits are each flash memory devices.

13. The circuit module of claim 7 further comprising a second trace that connects a third pin and a fourth pin of the second packaged integrated circuit.

14. The circuit module of claim 7 in which the first trace is comprised of conductive ink.

15. The circuit module of claim 7 in which the first trace resides at least in part in a channel disposed in the body of the second packaged integrated circuit.

16. A circuit module comprising:
a first packaged integrated circuit;
a second packaged integrated circuit stacked above the first packaged integrated circuit, the first and second packaged integrated circuits each being comprised of a body with leads emergent from at least one side of said body, the circuit module being connected to a mounting field by the leads of the first packaged integrated circuit and a selected one of plurality connective sites of the mounting field being connected to a selected lead of the first packaged integrated circuit which selected lead is connected to a first selected lead of the second packaged integrated circuit which first selected lead of the second packaged integrated circuit is connected to a first trace borne by the body of the second packaged integrated circuit and which first trace completes a connection between a second selected lead of the second packaged integrated circuit through the first selected lead of the second packaged integrated circuit and the selected lead of the first packaged integrated circuit to the selected one of the plural connective sides of the mounting field.

17. The circuit module of claim 16 in which a second trace connects a selected lead of a first function to a selected lead of a second function on the second packaged integrated circuit.

18. The circuit module of claim 16 in which the first trace is comprised of conductive ink.

19. The circuit module of claim 16 in which the first trace is comprised of conductive metal disposed on the body of the second packaged integrated circuit.

20. The circuit module of claim 16 in which at least one of the first and second packaged integrated circuits is a flash circuit.
